(19) United States
(12) Patent Application Publication
(10) Pub. No.: US 2015/0030838 A1
(43) Pub. Date: Jan. 29, 2015

(54) GLASS SHEET

(71) Applicant: SAINT-GOBAIN GLASS FRANCE, Courbevoie (FR)

(72) Inventors: Julien Sellier, Paris (FR); Rene Gy, Bondy (FR); Stephanie Pelletier, Paris (FR)

(21) Appl. No.: 14/384,629

(22) PCT Filed: Mar. 13, 2013
(86) PCT No.: PCT/FR2013/050523

§ 371 Date: Sep. 11, 2014

(30) Foreign Application Priority Data
Mar. 15, 2012 (FR) 1252320

(51) Int. Cl. C03C 21/00; C03C 3/085; H01L 31/048

(52) U.S. Cl. CPC C03C 21/002; H01L 31/0481; C03C 3/085
USPC 428/220; 65/30.14

(57) ABSTRACT

A glass sheet, the composition of which is of the lithium aluminosilicate type and includes at most 1% by weight of sodium oxide, the thickness of which is at most 2 mm, having a surface region under compression obtained by ion exchange and a central region under tension, such that the flexural stress at break in a ring-on-tripod test is at least 50 MPa, after Vickers indentation under a load of 120 N.

The invention relates to the field of thin glass sheets. It relates more particularly to thin glass sheets capable of withstanding violent impacts.

Thin glass sheets are frequently employed as protective glass, visual display window or also screen for various electronic devices, in particular pocket or portable devices, such as, for example, smart phones, personal digital assistants (sometimes known as “PDAs”), tablets, digital cameras, multimedia players, computers, television or display screens, and the like. For reasons related to the weight, it is also advantageous to employ thin glass sheets as cover glass for solar thermal or photovoltaic collectors.

The glass sheets used in such devices or applications are capable of being highly stressed from a mechanical viewpoint: repeated contacts with hard and sharp objects, impacts of projectiles, being dropped, and the like.

In order to increase their impact strength, it is known to create a surface region under compression and a central region under tension by processes of thermal tempering or of ion exchange (which is sometimes referred to as “chemical tempering”). In the latter case, the surface replacement of an ion of the glass sheet (generally an alkali metal ion, such as sodium) by an ion with a greater ionic radius (generally an alkali metal ion, such as potassium) makes it possible to create, on the surface of the glass sheet, residual compressive stresses down to a certain depth. Throughout the text, the depth corresponds, along a transverse cross section, to a distance between a point under consideration and the closest surface of the glass sheet, measured along a normal to said surface. Likewise, throughout the continuation of the text, the stresses are parallel to the surface of the glass sheet and are thickness stresses, in the sense that, with the exception of the edge regions, the mean of the stresses over the entire thickness of the glass sheet is zero. The surface compressive stresses are in effect balanced by the presence of a central region under tension. There thus exists a certain depth at which the transition between compression and tension takes place. The stress profile corresponds to the plot of the stress (whether compressive or tensile) along a transverse cross section as a function of the distance to one of the faces of the glass sheet, measured along a normal to said face.

In the majority of the abovementioned applications, it is also important for the glass sheet not to fragment in the event of breaking. The term “fragmentation” is understood to mean the ability of the glass to break with the formation of a multitude of small fragments (indeed even of particles) capable of being ejected or, if they remain in place, of greatly reducing the visibility through the sheet.

In general, these two requirements (impact strength and resistance to fragmentation) are contradictory as the strengthening provided by the presence of residual stresses after tempering is accompanied by core tensions which will promote the fragmentation.

It is an aim of the invention to reconcile these two requirements by providing glass sheets capable of maintaining a high mechanical strength even after having been heavily damaged during their use, as is the case, for example, as a result of being repeatedly dropped, while nevertheless exhibiting a low aptitude for fragmentation.

To this end, a subject matter of the invention is a glass sheet, the composition of which is of the lithium aluminosilicate type and comprises at most 1% by weight of sodium oxide, the thickness of which is at most 2 mm, having a surface region under compression obtained by ion exchange and a central region under tension, such that the flexural stress at break in a “ring-on-tripod” test is at least 50 MPa, after Vickers indentation under a load of 120 N.

The protocol for measuring the stress at break is described in more detail below, in the part of the present text describing the examples according to the invention.

The surface region under compression is obtained by ion exchange, preferably using sodium ions. Further details with regard to this process are given in the continuation of the present description.

The thickness th of the glass sheet is preferably at most 1.5 mm, indeed even 1.1 mm. The thickness of the glass sheet is preferably at least 0.25 mm, in particular 0.5 mm. The lateral dimensions of the glass sheet depend on the use targeted. At least one dimension is generally less than or equal to 40 cm, in particular 30 cm, indeed even 20 cm. The surface area of the glass sheet is generally at most 0.2 m², indeed even 0.1 m². In the applications of cover glass for solar collectors, the surface area of the glass sheet will, on the other hand, generally be at least 1 m².

The exchange depth is preferably at least 40 micrometers, in particular 50 micrometers, and/or at most 500 micrometers, indeed even 300 micrometers. The method for measuring the depth of exchange is described in detail in the part of the description devoted to the examples.

In order to reduce the ability of the glass to fragment, the parameter K, defined as being the square root of the integral in the central region under tension of the square of the stress, is preferably at most 1.4 MPa·m^{1/2}, indeed even 1.3 MPa·m^{1/2}. By limiting the value of the factor K, the breaking of the glass sheet is characterized on the contrary by the presence of a small number of cracks which, while being unsightly, have a reduced impact on the visibility and on the propensity to eject fragments.

The inventors have been able to demonstrate the fact that the glasses according to the invention exhibit, surprisingly, a markedly improved strength after being severely damaged (for example in the event of impact), despite a slight fragmentation after breaking.

The flexural stress at break in a “ring-on-tripod” test of the glass sheets according to the invention is preferably at least 80 MPa, in particular 100 MPa, after Vickers indentation under a load of 120 N. The flexural stress at break in a “ring-on-tripod” test is advantageously at least 300 MPa after Vickers indentation under a load of 10 N.

The glass of lithium aluminosilicate type is preferably such that its chemical composition comprises the following oxides in the ranges of contents by weight defined below:

| | |
|---|---|
| SiO₂ | 50-80%, in particular 60-75%, |
| Al₂O₃ | 12-30%, in particular 17-23%, |
| Li₂O | 1-10%, in particular 1-5%. |

The content by weight of CaO is advantageously at most 3%, in particular 2% and even 1% or 0.5%. This is because it turns out that the calcium oxide reduces the resistance of the glass to cracking under indentation.

A preferred glass is such that its chemical composition comprises the following oxides in the ranges of contents by weight defined below:

| SiO₂ | 52-75%, in particular 65-70% |
|---|---|
| Al₂O₃ | 15-27%, in particular 18-19.8% |
| Li₂O | 2-10%, in particular 2.5-3.8% |
| Na₂O | 0-1%, in particular 0-0.5% |
| K₂O | 0-5%, in particular 0-1% |
| CaO | 0-0.5%, in particular 0-0.1% |
| ZnO | 0-5%, in particular 1.2-2.8% |
| MgO | 0-5%, in particular 0.55-1.5% |
| BaO | 0-5%, in particular 0-1.4% |
| SrO | 0-3%, in particular 0-1.4% |
| TiO₂ | 0-6%, in particular 0-2% |
| ZrO₂ | 0-3%, in particular 0-2.5% |
| P₂O₅ | 0-8%. |

As is customary in the art, the chemical composition of the glass sheet corresponds to the chemical composition outside the exchanged regions, thus in the central region.

The glass of lithium aluminosilicate type is capable of being reinforced by an exchange of lithium ions by sodium ions. The rate of exchange of this type of glass is particularly high, as is its scratch resistance.

Another subject matter of the invention is:

an electronic device, in particular a pocket or portable electronic device, such as in particular a smart phone, personal digital assistant, digital camera, multimedia player, computer, tablet or television, comprising at least one glass sheet according to the invention, as protective glass, visual display window, screen or decorative element, which may or may not be transparent,
a solar thermal or photovoltaic collector comprising at least one glass sheet according to the invention.

A further subject matter of the invention is a process for obtaining a glass sheet according to the invention, comprising stages of melting the glass, of forming, of cutting and of ion exchange.

The forming stage can be carried out by different processes which are moreover known, such as the float glass process, in which the molten glass is poured onto a bath of molten tin, the rolling process between two rolls, the “fusion-draw” process, in which the molten glass overflows from a channel and will form a sheet by gravity, or also the “down-draw” process, in which the molten glass flows downward via a slit, before being drawn to the desired thickness and simultaneously cooled. The cutting stage is advantageously followed by a stage of shaping or polishing the edges and/or the surface, before the ion exchange stage.

The ion exchange consists in replacing a portion of the lithium ions of the glass sheet with alkali metal ions having a greater ionic radius, typically sodium ions. Other ions can also be used, such as potassium, rubidium or cesium ions, indeed even thallium, silver or copper ions.

The ion exchange is generally carried out by placing the glass sheet in a bath filled with a molten salt of the desired alkali metal ion. A high temperature, but below the glass transition temperature of the glass to be treated, makes it possible to initiate a phenomenon of interdiffusion, impacting first the surface layers of the glass.

It is also possible to carry out the ion exchange by depositing a paste at the surface of the glass. The ion exchange can also be facilitated by applying an electric field or ultrasound.

At least one ion exchange stage is preferably carried out using a molten sodium salt chosen from a nitrate, sulfate, chloride or any one of their mixtures. A mixture of sodium salt and of potassium salt makes it possible to limit the strength of the stresses. Pure sodium nitrate is particularly preferred.

The exchange temperature and time are to be adjusted as a function of the composition of the glass, of its thickness and of the desired profile of stresses.

The nonlimiting examples which follow illustrate the present invention.

The glass used for the comparative examples C1 and C2 is a sodium aluminosilicate having the following composition by weight:

| | |
|---|---|
| SiO₂ | 62% |
| Al₂O₃ | 8% |
| Na₂O | 12.5% |
| K₂O | 9% |
| MgO | 7.5% |
| CaO | 0.5%. |

Glass sheets with this composition were produced by the float glass process at a thickness of 3 mm and then polished in order to achieve a thickness th of approximately 1 mm. These glass sheets were subjected to various ion exchange treatments carried out by immersing the glass sheet in a bath of molten potassium nitrate.

The glass used for examples 1 and 2 according to the invention is a lithium aluminosilicate exhibiting the following composition by weight:

| | |
|---|---|
| SiO₂ | 68.2% |
| Al₂O₃ | 19.0% |
| Li₂O | 3.5% |
| MgO | 1.2% |
| ZnO | 1.6% |
| TiO₂ | 2.6% |
| ZrO₂ | 1.7% |
| Na₂O + K₂O | <0.5% |

Glass sheets with this composition were produced at a thickness of 4 mm and then polished in order to achieve a thickness th of approximately 1 mm. These glass sheets were subjected to various ion exchange treatments carried out by immersing the glass sheet in a bath of molten sodium nitrate.

The exchange temperature T (in ° C.) and the exchange time t (in hours), the thickness th (in mm), the exchange depth H (in micrometers), the value of the core stress Sₑ (in MPa) and the number of fragments when the glass is smashed are summarized in table 1 below for the various examples.

The exchange depth is determined using measurements of the weight of the sample before and after chemical tempering. More specifically, the depth H is given by the following formula:

$$H = \frac{Δ w}{w} \frac{M}{Δ M} \frac{\sqrt{π} th}{α}$$

In this formula, w is the weight of the sample before tempering, Δw is the variation in weight due to the tempering, M is the molar mass of the glass before tempering, ΔM is the difference in molar mass between the alkali metal oxides entering the glass and those exiting from the glass, th is the thickness of the glass and a is the initial molar concentration of the alkali metal oxide exiting from the glass during the exchange (Na₂O for the comparative examples, Li₂O for the examples according to the invention).

The core stress S_{c} is drawn from the stress profile, determined using a polarizing microscope equipped with a Babinet compensator. Such a method is described by H. Aben and C. Guillemet in “Photoelasticity of Glass”, Springer Verlag, 1993, pp. 65, 123, 124, 146. The parameter K can also be calculated from this stress profile.

In order to measure the fragmentation, the test specimens are coated with an adhesive film on both faces and then the glass is impacted at 1 cm from one of its corners using a carbide tip and a hammer. The count of the number of fragments is carried out at at least 2 cm from the point of impact, in a 3×3 cm² square. It is considered that a glass is not fragmented when the number of fragments is less than or equal to 2.

TABLE 1

| | C1 | 1 | C2 | 2 |
|---|---|---|---|---|
| T (° C.) | 380 | 340 | 500 | 395 |
| t (h) | 34 | 1 | 15 | 4 |
| t (mm) | 1.0 | 1.0 | 1.0 | 1.0 |
| H (μm) | 55 | 55 | 233 | 232 |
| S_{c} (MPa) | 38 | 12 | 49 | 46 |
| Fragments | 1 | 1 | 2 | 2 |

The results obtained in terms of stress at break after indentation are presented in table 2 below.

The ring-on-tripod flexural stress at break after indentation is measured under ambient temperature and humidity conditions in the following way. Test specimens of 70×70 mm² are cut out from a glass sheet which has not been subjected to any treatment after its manufacture. After ion exchange, the test specimens are cleaned with water and dried.

Any one face of each test specimen is then coated with an adhesive film on a face which will be subsequently compressed. The role of this film is to make it possible to locate the origin of breaking.

The indentation is produced on the face opposite the adhesive film using weights placed on top of a Vickers tip. The test specimen is positioned under the tip so that the indentation is produced in the middle of the test specimen, to within 1 mm.

The tip is brought down onto the test specimen by virtue of an Instron 4505 device equipped with a 5 kN force sensor. In the starting position, the tip is placed between 2 and 5 mm above the test specimen. The tip is then brought toward the glass at a rate of 10 mm/min. After contact between the tip and the glass, the force applied by the device becomes zero and only the weights placed on the tip bring about the indentation of the glass. The indentation lasts 20 seconds and then the tip is raised by the device.

The glass is subsequently stored for at least 12 h in order to stabilize the propagation of the cracks. In the event of breakage after indentation but before the flexural test, the flexural stress at break is declared to be zero.

The ring-on-tripod flexural test is carried out using an Instron 4400R device, regulated with a rate of descent of the crosshead of 2 mm/min, equipped with a 10 kN force sensor, with a ring having a diameter of 10 mm with a torus having a radius of 1 mm, attached at the end of the Instron device, and with a base to which three balls with a radius of 5 mm are adhesively bonded, these balls being positioned at 120° over a circle with a radius of 20 mm, the center of which is coincident with the center of the ring.

The test specimen is placed between these three balls and the ring, so that the indentation mark is aligned with the center of the ring, to within 1 mm. An increasing force is then applied to the ring until the test specimen breaks. Only the test specimens for which the origin of breakage is under the ring are counted. The stress at break as a function of the force at break and of the thickness of the test specimen is given by the following formula:

$${σ}_{( MPa )} = \frac{0.847 \times {Force}_{( N )}}{{thickness}_{( mm )}^{2}}$$

TABLE 2

| | |
|---|---|
| Indentation | Stress at break (MPa) |

| (N) | C1 | 1 | C2 | 2 |
|---|---|---|---|---|
| 10 | 394 | 426 | 186 | 427 |
| 60 | 40 | 54 | 143 | 253 |
| 80 | 0 | 63 | 127 | 166 |
| 120 | 0 | 56 | 0 | 108 |

The choice of a composition of lithium aluminosilicate type thus proves to be particularly advantageous in terms of impact strength and generally resistance to severe damage by contact, for an analogous ion exchange (same depth H and same maximum tensile stress). In addition, the choice of stresses at break for the strongest indentations makes it possible to introduce a particularly high impact strength.

1. A lithium aluminosilicate glass sheet, a composition of which comprises at most 1% by weight of sodium oxide, a thickness of which is at most 2 mm, having a surface region under compression obtained by ion exchange and a central region under tension, such that a flexural stress at break in a ring-on-tripod test is at least 50 MPa, after Vickers indentation under a load of 120 N.

2. The lithium aluminosilicate glass sheet as claimed in claim 1, wherein the flexural stress at break in a ring-on-tripod test is at least 100 MPa, after Vickers indentation under a load of 120 N.

3. The lithium aluminosilicate glass sheet as claimed in claim 1, such that wherein the flexural stress at break in a ring-on-tripod test is at least 300 MPa, after Vickers indentation under a load of 10 N.

4. The lithium aluminosilicate glass sheet as claimed in claim 1, the thickness of which is at most 1.5 mm and at least 0.25 mm.

5. The lithium aluminosilicate glass sheet as claimed in claim 4, the thickness of which is at most 1.1 mm.

6. The lithium aluminosilicate glass sheet as claimed in claim 1, wherein an exchange depth is at least 40 micrometers.

7. The lithium aluminosilicate glass sheet as claimed in claim 1, such that the surface region under compression is obtained by ion exchange using sodium ions.

8. The lithium aluminosilicate glass sheet as claimed in claim 1, wherein the chemical composition comprises the following oxides in the ranges of contents by weight defined below:

| | |
|---|---|
| SiO₂ | 50-80% |
| Al₂O₃ | 12-30% |
| Li₂O | 1-10%. |

9. The lithium aluminosilicate glass sheet as claimed in claim 8, wherein the content by weight of CaO is at most 3%.

10. The lithium aluminosilicate glass sheet as claimed in claim 8, wherein the chemical composition comprises the following oxides in the ranges of contents by weight defined below:

| | |
|---|---|
| SiO₂ | 52-75% |
| Al₂O₃ | 15-27% |
| Li₂O | 2-10% |
| Na₂O | 0-1% |
| K₂O | 0-5% |
| CaO | 0-0.5% |
| ZnO | 0-5% |
| MgO | 0-5% |
| BaO | 0-5% |
| SrO | 0-3% |
| TiO₂ | 0-6% |
| ZrO₂ | 0-3% |
| P₂O₅ | 0-8%. |

11. An electronic device, comprising at least one lithium aluminosilicate glass sheet as claimed in claim 1, as protective glass, visual display window, screen or decorative element.

12. A pocket or portable electronic device, comprising at least one lithium aluminosilicate glass sheet as claimed in claim 1 as protective glass.

13. A solar thermal or photovoltaic collector, comprising at least one lithium aluminosilicate glass sheet as claimed in claim 1.

14. A process for obtaining a lithium aluminosilicate glass sheet as claimed in claim 1, comprising stages of melting the glass, of forming, of cutting and of ion exchange.

15. The process as claimed in claim 14, wherein at least one ion exchange stage is carried out using a molten sodium salt chosen from a nitrate, sulfate, chloride or any one of their mixtures.

16. The lithium aluminosilicate glass sheet as claimed in claim 6, wherein the exchange depth is at least 300 micrometers.

17. The lithium aluminosilicate glass sheet as claimed in claim 9, wherein the content by weight of CaO is at most 1%.

18. The lithium aluminosilicate glass sheet as claimed in claim 10, wherein the chemical composition comprises the following oxides in the ranges of contents by weight defined below:

| | |
|---|---|
| SiO₂ | 65-70% |
| Al₂O₃ | 18-19.8% |
| Li₂O | 2.5-3.8% |
| Na₂O | 0-0.5% |
| K₂O | 0-1% |
| CaO | 0-0.1% |
| ZnO | 1.2-2.8% |
| MgO | 0.55-1.5% |
| BaO | 0-1.4% |
| SrO | 0-1.4% |
| TiO₂ | 0-2% |
| ZrO₂ | 0-2.5% |

19. The electronic device as claimed in claim 11, wherein said electronic device is a smart phone, personal digital assistant, digital camera, multimedia player, computer, tablet or television.
